(19) United States
(12) Patent Application Publication
(10) Pub. No.: US 2024/0112057 A1
(43) Pub. Date: Apr. 4, 2024

(54) OPTICS-INTEGRATED CONFINEMENT APPARATUS SYSTEM

(71) Applicant: Quantinuum LLC, Broomfield, CO (US)

(72) Inventors: Matthew Bohn, Broomfield, CO (US); Christopher John Carron, Broomfield, CO (US); Bryan DeBono, Broomfield, CO (US); Chris Ertsgaard, Champlin, MN (US); Robert D. Horning, Lakeville, MN (US); Molly Krogstad, Broomfield, CO (US); Patricia Lee, Louisville, CO (US); Lora Nugent, Broomfield, CO (US); Adam Jay Ollanik, Boulder, CO (US); Mary Rowe, Broomfield, CO (US); Steve Sanders, Broomfield, CO (US); Alex Zolot, Broomfield, CO (US)

(21) Appl. No.: 18/475,479

(22) Filed: Sep. 27, 2023

Related U.S. Application Data
(60) Provisional application No. 63/378,124, filed on Oct. 3, 2022.

(51) Int. Cl. G06N 10/40; H01L 33/06

(52) U.S. Cl. CPC G06N 10/40; H01L 33/06

(57) ABSTRACT

An optics-integrated confinement apparatus system comprises a confinement apparatus chip having a confinement apparatus formed thereon and having at least one apparatus optical element disposed and/or formed thereon.

### CROSS-REFERENCE TO RELATED APPLICATIONS

This application claims priority to U.S. Application No. 63/378,124, filed Oct. 3, 2022, the content of which is incorporated herein by reference in its entirety.

### TECHNICAL FIELD

Various embodiments relate to apparatuses, systems, and methods relating to optics-integrated confinement apparatus, quantum processors comprising optics-integrated confinement apparatus, quantum computers comprising optics-integrated confinement apparatus, and/or the like. An example embodiment relates to an optics-integrated confinement apparatus system comprising a confinement apparatus chip having at least one optical element disposed and/or formed thereon and/or therein.

### BACKGROUND

When using an ion trap to perform quantum computing, gates and other functions of the quantum computer are performed by applying laser beams to ions contained within the ion trap. Delivering these laser beams to a large-scale quantum computer is a significant challenge due to the low ion height above the trap, the Rayleigh range of the laser beams, and the amount of laser power that needs to be delivered to an ion within the trap to perform the functions of the quantum computer. Through applied effort, ingenuity, and innovation many deficiencies of prior laser beam application techniques have been solved by developing solutions that are structured in accordance with the embodiments of the present invention, many examples of which are described in detail herein.

### BRIEF SUMMARY OF EXAMPLE EMBODIMENTS

Example embodiments provide apparatuses, systems, and corresponding methods for optics-integrated confinement apparatuses, various systems comprising at least one optics-integrated confinement apparatus, including quantum processors (e.g., quantum charge coupled device (QCCD)-based quantum processors) and/or quantum computers comprising at least one optics-integrated confinement apparatus. In various embodiments, an optics-integrated confinement apparatus system comprises a confinement apparatus chip on which electrical components are disposed and/or formed. The electrical components include electrodes configured for defining confinement regions within which quantum objects may be confined. In various embodiments, a quantum object is a neutral or ionic atom; neutral, ionic, or multipole molecule; quantum particle; quantum dot; and/or other object having quantum states that can be manipulated and/or controlled.

In various embodiments, the confinement apparatus chip further includes one or more optical elements that are disposed and/or formed thereon and/or therein. In various embodiments, the one or more optical elements are configured to provide respective optical manipulation signals to respective object locations defined within the confinement regions of the confinement apparatus and/or to receive/detect respective optical signals emitted by respective quantum objects located at respective object locations. In various embodiments, the one or more optical elements include passive and/or active optical elements.

In various embodiments, the confinement apparatus chip defines an apparatus plane. In various embodiments, the optics-integrated confinement apparatus system comprises one or more bridge chips that each define a respective bridge plane. The respective bridge planes are coplanar with the apparatus plane. Each of the one or more bridge chips may have one or more optical elements disposed and/or formed thereon and/or therein. In various embodiments, the optics-integrated confinement apparatus system comprises one or more delivery chips. In various embodiments, a delivery chip may be disposed within the cryogenic and/or vacuum chamber within which the confinement apparatus chip is disposed or external thereto. An example of a delivery chip is a cloud chip. In various embodiments, the optics-integrated confinement apparatus system comprises one or more cloud chips that each define a respective cloud plane that is parallel to the apparatus plane but not coplanar with the apparatus plane. Each of the one or more cloud chips may have one or more optical elements disposed and/or formed thereon and/or therein.

According to an aspect of the present disclosure, an optics-integrated confinement apparatus system is provided. In an example embodiment, the optics-integrated confinement apparatus system comprises a confinement apparatus chip having a confinement apparatus formed thereon and having at least one apparatus optical element disposed and/or formed thereon.

In an example embodiment, the at least one apparatus optical element comprises at least one of a diffractive optical element, a passive metasurface, an active metasurface, an optical modulator, a low loss waveguide, an amplifier, an laser, a photodetector, a grating coupler, a beam splitter, an edge coupler, an optical local oscillator, a taper, a reference cavity, light absorbing structure, anti-reflection coating, optical routing element, or resonant structure.

In an example embodiment, the optics-integrated confinement apparatus system further comprises at least one of (a) a bridge chip having at least one bridge optical element disposed and/or formed thereon or (b) a delivery chip having at least one delivery optical element disposed and/or formed thereon.

In an example embodiment, the at least one bridge optical element and/or the at least one delivery optical element comprises at least one of a diffractive optical element, a passive metasurface, an active metasurface, an optical modulator, a low loss waveguide, an amplifier, an on-chip laser, a photodetector, a grating coupler, an optical splitter, an edge coupler, an optical local oscillator, a taper, a reference cavity, light absorbing structure, anti-reflection coating, optical routing element, or resonant structure.

In an example embodiment, the delivery chip is a cloud chip.

In an example embodiment, optics-integrated confinement apparatus system is configured for operation under cryogenic and/or ultra-high vacuum conditions.

In an example embodiment, at least one of (a) the at least one apparatus optical element, (b) the at least one bridge optical element, or (c) the at least one delivery optical element is configured to be coupled to an optical fiber configured to provide a manipulation signal generated outside of a cryogenic and/or vacuum chamber within which the optics-integrated confinement apparatus system is disposed to the at least one of (a) the at least one apparatus optical element, (b) the at least one bridge optical element, or (c) the at least one delivery optical element.

In an example embodiment, the at least one of (a) the at least one apparatus optical element, (b) the at least one bridge optical element, or (c) the at least one delivery optical element is configured to be coupled to the optical fiber via a fiber block.

In an example embodiment, the optics-integrated confinement apparatus system is fabricated at least in part using a pick-and-place technique.

According to an aspect, a quantum processor is provided. In an example embodiment, the quantum processor comprises a cryogenic and/or vacuum chamber; and an optics-integrated confinement apparatus system disposed within the cryogenic and/or vacuum chamber. The optics-integrated confinement apparatus system comprises a confinement apparatus chip having a confinement apparatus formed thereon and having at least one apparatus optical element disposed and/or formed thereon.

According to an aspect a quantum processor is provided. In an example embodiment, the quantum computer comprises a quantum processor and a controller. The controller is configured to control one or more active optical elements disposed on at least one of the confinement apparatus chip, bridge chip, or cloud chip. The quantum processor comprises a cryogenic and/or vacuum chamber; and an optics-integrated confinement apparatus system disposed within the cryogenic and/or vacuum chamber. The optics-integrated confinement apparatus system comprises a confinement apparatus chip having a confinement apparatus formed thereon and having at least one apparatus optical element disposed and/or formed thereon.

According to another aspect, a QCCD-based quantum system is provided. In an example embodiment, the QCCD-based quantum system comprises a confinement apparatus (a) defining a plurality of positions, (b) operable to confine quantum objects, and (c) formed on a confinement apparatus chip. The confinement apparatus is operable to confine respective quantum objects at respective positions of the plurality of positions and cause transportation of respective quantum objects between the respective positions of the plurality of positions. The QCCD-based quantum system further comprises a signal manipulation system configured to cause delivery of optical signals to at least one of the respective positions. The signal manipulation system comprises at least one apparatus optical element disposed and/or formed on the confinement apparatus chip.

In an example embodiment, the at least one apparatus optical element comprises at least one of a diffractive optical element, a passive metasurface, an active metasurface, an optical modulator, a low loss waveguide, an amplifier, an laser, a photodetector, a grating coupler, a beam splitter, an edge coupler, an optical local oscillator, a taper, a reference cavity, a light absorbing structure, an anti-reflection coating, an optical routing element, or a resonant structures.

In an example embodiment, the signal management system further comprises at least one of (a) a bridge chip having at least one bridge optical element disposed and/or formed thereon or (b) a delivery chip having at least one delivery optical element disposed and/or formed thereon.

In an example embodiment, the at least one bridge optical element and/or the at least one delivery optical element comprises at least one of a diffractive optical element, a passive metasurface, an active metasurface, an optical modulator, a low loss waveguide, an amplifier, an on-chip laser, a photodetector, a grating coupler, an optical splitter, an edge coupler, an optical local oscillator, a taper, a reference cavity, a light absorbing structure, an anti-reflection coating, an optical routing element, or a resonant structures.

In an example embodiment, the delivery chip is a cloud chip.

In an example embodiment, the confinement apparatus and at least a portion of the signal management system is configured for operation under cryogenic and/or ultra-high vacuum conditions.

In an example embodiment, at least one of (a) the at least one apparatus optical element, (b) the at least one bridge optical element, or (c) the at least one delivery optical element is configured to be coupled to an optical fiber configured to provide a manipulation signal generated outside of a cryogenic and/or vacuum chamber within which the optics-integrated confinement apparatus system is disposed to the at least one of (a) the at least one apparatus optical element, (b) the at least one bridge optical element, or (c) the at least one delivery optical element.

In an example embodiment, the at least one of (a) the at least one apparatus optical element, (b) the at least one bridge optical element, or (c) the at least one delivery optical element is configured to be coupled to the optical fiber via a fiber block.

In an example embodiment, at least one of (a) the at least one apparatus optical element, (b) the at least one bridge optical element, or (c) the at least one delivery optical element is part of a photonic integrated circuit disposed and/or formed on a respective one of (i) the apparatus chip, (ii) bridge chip, or (iii) delivery chip and the at least one photonic integrated circuit disposed and/or formed on the respective one of (i) the apparatus chip, (ii) bridge chip, or (iii) delivery chip is fabricated at least in part using a pick-and-place technique.

In an example embodiment, the plurality of positions defines an array of positions and the signal management system is configured to selectively provide optical signals to set positions within the array of positions.

In an example embodiment, the signal management system is configured to selectively provide the optical signals to the set positions within the array of positions substantially simultaneously.

According to another aspect, a quantum processor is provided. In an example embodiment, the quantum processor comprises a cryogenic and/or vacuum chamber; and the QCCD-based quantum system disposed within the cryogenic and/or vacuum chamber.

According to yet another aspect, a quantum computer is provided. In an example embodiment, the quantum computer comprises the quantum processor and a controller configured to control one or more active optical elements disposed on at least one of the confinement apparatus chip, bridge chip, or delivery chip.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a schematic diagram illustrating an example quantum computing system comprising an optics-integrated confinement apparatus, according to an example embodiment.

FIG. 2 is a schematic top view of a portion of an optics-integrated confinement apparatus, according to an example embodiment.

FIG. 3 is a schematic cross-section view of an optics-integrated confinement apparatus, according to an example embodiment.

FIG. 4 provides a schematic diagram of an example controller of a quantum computer configured to control operation of one or more active optical elements of the optics-integrated confinement apparatus, according to various embodiments.

FIG. 5 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

Example embodiments provide apparatuses, systems, and corresponding methods for optics-integrated confinement apparatuses, various systems comprising at least one optics-integrated confinement apparatus, including quantum processors (e.g., quantum charge coupled device (QCCD)-based quantum processors) and/or quantum computers comprising at least one optics-integrated confinement apparatus. In various embodiments, an optics-integrated confinement apparatus system comprises a confinement apparatus chip on which electrical components are disposed and/or formed. The electrical components include electrodes configured for defining confinement regions within which quantum objects may be confined.

In various embodiments, an optics-integrated confinement apparatus system is a QCCD-based quantum system comprising a confinement apparatus configured for confining quantum objects and a signal management system wherein at least a portion of the signal management system (e.g., at least one apparatus optical element) is disposed on the same substrate and/or chip as the electrical components (e.g., electrodes) of the confinement apparatus. As used herein, the term apparatus optical element refers to an optical element formed and/or disposed on the confinement apparatus chip.

In various embodiments, the confinement apparatus chip further includes one or more optical elements that are disposed and/or formed thereon and/or therein. In various embodiments, the one or more optical elements are configured to provide respective optical manipulation signals to respective object locations defined within the confinement regions of the confinement apparatus and/or to receive/detect respective optical signals emitted by respective quantum objects located at respective object locations. In various embodiments, the one or more optical elements include passive and/or active optical elements.

In various embodiments, the confinement apparatus chip defines an apparatus plane. In various embodiments, the optics-integrated confinement apparatus system comprises one or more bridge chips that each define a respective bridge plane. The respective bridge planes are coplanar with the apparatus plane. Each of the one or more bridge chips may have one or more bridge optical elements disposed and/or formed thereon and/or therein. As used herein, a bridge optical element is an optical element formed and/or disposed on a bridge chip. In various embodiments, a bridge chip comprises zero or more inputs and one or more outputs. In various embodiments, a bridge chip is configured to provide manipulation signals and/or other optical signals to one or more optical elements disposed on the confinement apparatus chip. In various embodiments, a bridge chip may span regions that involve varying temperatures and/or pressures (e.g., within a cryogenic and/or vacuum chamber within which the confinement apparatus chip is disposed).

In various embodiments, the optics-integrated confinement apparatus system comprises one or more delivery chips. In various embodiments, a delivery chip is configured to provide manipulation signals and/or other optical signals to one or more optical elements disposed on the confinement apparatus chip, one or more bridge chips, and/or defined positions of the confinement apparatus. For example, in various embodiments, a delivery chip comprises one or more delivery optical elements. As used herein, a delivery optical element is an optical element disposed and/or formed on a delivery chip.

In various embodiments, a delivery chip may be disposed within the cryogenic and/or vacuum chamber within which the confinement apparatus chip is disposed or external thereto. In various embodiments, delivery chips may be configured in various physical orientations. For example, a delivery chip defines a delivery chip plane which may be disposed with various orientations with respect to the apparatus plane. For example, in an example embodiment, a delivery chip is mounted to a wall and/or shielding surface of the cryogenic and/or vacuum chamber within which the confinement apparatus chip is disposed.

An example of a delivery chip is a cloud chip. In various embodiments, the optics-integrated confinement apparatus system comprises one or more cloud chips that each define a respective cloud plane that is parallel to the apparatus plane but not coplanar with the apparatus plane. Each of the one or more cloud chips may have one or more optical elements disposed and/or formed thereon and/or therein.

In various embodiments, a bridge chip and/or delivery chip may be disposed in a region of substantially constant temperature and/or pressure conditions. For example, the bridge chip and/or delivery chip may be disposed within an action region of the cryogenic and/or vacuum chamber such that the bridge chip and/or delivery chip is operated under cryogenic and/or ultra-high vacuum conditions. In various embodiments, the confinement apparatus chip is disposed within the action region of the cryogenic and/or vacuum chamber and configured to be operated under cryogenic and/or ultra-high vacuum conditions. The bridge chip and/or delivery chip may be disposed in an intermediary area of the cryogenic and/or vacuum chamber (e.g., within the cryogenic and/or vacuum chamber but in an intermediate region thereof that experiences intermediate temperatures and/or pressures that are between ambient temperature and/or pressure outside of the cryogenic and/or vacuum chamber and the very low cryogenic temperatures and ultra-high vacuum conditions within the action region of the cryogenic and/or vacuum chamber). In an example embodiment, a delivery chip may be disposed outside of the cryogenic and/or vacuum chamber. In various embodiments, a bridge chip and/or delivery chip may be partially disposed in and/or extend across one or more regions of the cryogenic and/or vacuum chamber. As used herein, the regions of the cryogenic and/or vacuum chamber include the action region of the cryogenic and/or vacuum chamber (e.g., having very low temperatures and ultra-high vacuum conditions), the intermediate region of the cryogenic and/or vacuum chamber (e.g., having intermediate temperatures and intermediate pressures), and an ambient region (directly) outside of the cryogenic and/or vacuum chamber (e.g., having ambient/room temperatures and/or ambient/atmospheric pressure). For example, a portion of a bridge chip and/or delivery chip may be disposed in the action region of the cryogenic and/or vacuum chamber and a portion of the bridge chip may be disposed in the intermediate region of the cryogenic and/or vacuum chamber.

In various embodiments, the confinement apparatus chip defines a plurality and/or an array of defined positions. For example, the confinement apparatus chip may be configured such that when appropriate voltage signals are applied to electrical components (e.g., electrodes) thereof, an electric potential is generated that is configured to confine quantum objects at the defined positions. In various embodiments, a sub-array of defined positions may be configured for performing a particular function (e.g., a reading function, performance of a single qubit or multi-qubit (e.g., two qubit) gate, and/or the like. In various embodiments, the optical elements disposed on the confinement apparatus chip, bridge chip, and/or delivery chip(s) that are configured for performance of the particular function are arrayed on their respective chips/substrates accordingly.

In various embodiments, the optics-integrated confinement apparatus system is part of a system (e.g., quantum processor, quantum computer, and/or other atomic and/or quantum system) comprising a signal management system. For example, in various embodiments, a QCCD-based quantum system is provided comprising a confinement apparatus and a signal management system wherein one or more optical elements of the signal management system are formed and/or disposed on the confinement apparatus chip on which the confinement apparatus is formed and/or disposed. For example, the system may comprise a signal management system configured to generate, provide, control parameters of (e.g., wavelength, intensity, phase, polarization, and/or the like) of electromagnetic signals applied to one or more positions within the optics-integrated confinement apparatus system for the purpose of controlling the quantum state of one or more quantum objects confined by the optics-integrated confinement apparatus. In various embodiments, one or more of the components of the signal management system (active and/or passive components) are formed and/or disposed on the confinement apparatus chip itself, a bridge chip, and/or a cloud chip.

For example, the signal management system comprises active and/or passive optical elements respectively configured for generating, providing, collecting/detecting, and/or controlling parameters of manipulation signals applied to various positions defined by the optics-integrated confinement apparatus. In various embodiments, the optical elements of the signal management system comprise one or more diffractive optical elements, passive metasurfaces, active metasurfaces, optical modulators, low loss waveguides, amplifiers, on-chip lasers, photodetectors, grating couplers, beam splitters, edge couplers, optical local oscillators, tapers, reference cavities, light absorbing structures, anti-reflection coatings, optical routing elements, resonant structures, and/or the like. In various embodiments, various optical elements of the signal management system have electronic components associated therewith (e.g., the optical elements may be active optical elements with electrically controlled aspects) and other optical elements of the signal management system do not have electronic components associated therewith (e.g., the optical elements may be passive optical elements and/or active elements controlled via a technique other than electric signal-based control).

In various embodiments, a quantum object is a neutral or ionic atom; neutral, ionic, or multipole molecule; quantum particle; quantum dot; and/or other object having quantum states that can be manipulated and/or controlled. The quantum object may be qubit quantum object of a quantum object crystal comprising two or more quantum objects, with, in an example embodiment, the two or more quantum objects of the quantum object crystal comprising, for example, ions of at least two different atomic numbers. In an example embodiment, the optics-integrated confinement apparatus system is an ion trap (e.g., a surface ion trap, Paul trap, and/or the like) having one or more optical elements integrated therein. For example, the ion trap may be formed, defined, and/or disposed on a confinement apparatus chip. The confinement apparatus chip may be associated with one or more bridge chips and/or one or more cloud chips. The apparatus chip, bridge chip(s), and/or cloud chip(s) may have one or more optical elements formed and/or disposed thereon and/or therein.

Conventionally, laser beams are provided to positions within an ion trap through the use of external lasers and free space optics configured to provide the laser beams to specific positions within the ion trap. However, the amount of space required for such beam paths, even to provide laser beams to a relatively small number of defined positions of the ion trap, is significant (e.g., a few square meters). Additionally, the accuracy with which the laser beams may be provided to the positions within the ion trap through such conventional means can limit the density of the defined positions of ion trap. Moreover, ion traps are generally utilized within a cryogenic and/or vacuum chamber. As such, the laser beams must be passed through the cryogenic and/or vacuum chamber and any radiation and/or thermal shields therein. Thus, a technical problem exists as to how to provide manipulation signals to a quantum object confinement apparatus that is able to scale with the size and/or dimensions of the quantum object confinement apparatus efficiently and accurately. These technical problems are compounded as the quantum object confinement apparatus is increased in size (e.g., as the number of positions defined for the quantum object confinement apparatus increases).

Various embodiments provide technical solutions to these technical problems. In particular, in various embodiments, optical elements of the signal management system are incorporated and/or integrated into an optics-integrated confinement apparatus. For example, one or more optical elements of the signal management system are disposed within the cryogenic and/or vacuum chamber. For example, one or more optical components of the signal management system are disposed on the confinement apparatus chip (which comprises the electrical elements that define the confinement apparatus and the positions thereof), one or more bridge chips, and/or one or more cloud chips of the optics-integrated confinement apparatus. These one or more optical elements include passive and/or active optical elements. For example, in an example embodiment, a manipulation signal is generated by an on-chip laser and/or the like formed on the confinement apparatus chip, bridge chip, and/or cloud chip. In various embodiments, the one or more elements formed and/or disposed on and/or in the confinement apparatus chip, bridge chip(s), and/or cloud chip(s) reduce the spatial requirements for free space optics beam path configurations, number of cryogenic and/or vacuum chamber pass throughs, and/or the like. Furthermore, the configuration of the optics-integrated confinement apparatus system of various embodiments reduces the additional technical problems of signal management systems of larger confinement apparatuses. Thus, various embodiments provide technical solutions to technical problems regarding how to provide manipulation signals to an array of defined positions of a confinement apparatus such that manipulation signals efficiently and effectively provided to the defined positions, even when the defined positions form a two or three-dimensional array.

### Example Quantum Computing System Comprising an Atomic Object Confinement Apparatus

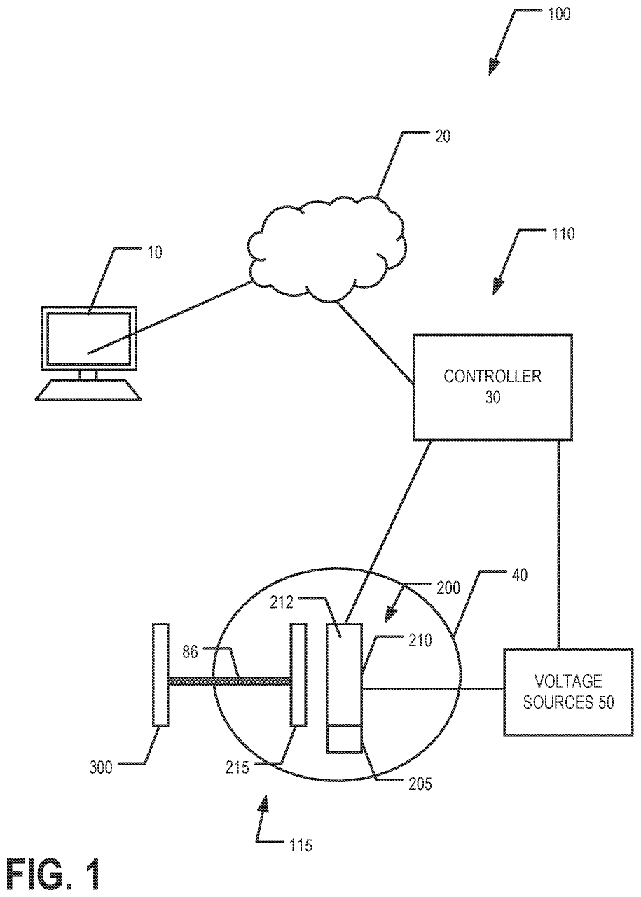

FIG. 1 provides a schematic diagram of an example quantum computing system 100 comprising on optics-integrated confinement apparatus system 200, in accordance with an example embodiment. In various embodiments, the optics-integrated confinement apparatus system 200 comprises a confinement apparatus chip 210, one or more bridge chips 205, one or more cloud chips, and/or the like. In various embodiments, the optics-integrated confinement apparatus system 200 is disposed within a cryogenic and/or vacuum chamber 40. For example, the confinement apparatus chip 210, one or more bridge chips 205, and/or one or more delivery chips are disposed within the cryogenic and/or vacuum chamber 40. In various embodiments, the electrical elements that define and/or form the confinement apparatus 212 are formed and/or disposed on the confinement apparatus chip 210.

In various embodiments, the confinement apparatus chip 210 defines an apparatus plane. In various embodiments, the optics-integrated confinement apparatus system comprises one or more bridge chips that each define a respective bridge plane. The respective bridge planes are coplanar with the apparatus plane. Each of the one or more bridge chips may have one or more optical elements disposed and/or formed thereon and/or therein. In various embodiments, the optics-integrated confinement apparatus system comprises one or more cloud chips that each define a respective cloud plane that is parallel to the apparatus plane but not coplanar with the apparatus plane. Each of the one or more cloud chips may have one or more optical elements disposed and/or formed thereon and/or therein.

In various embodiments, the quantum computing system 100 comprises a signal management system. In various embodiments the signal management system comprises one or more optical elements formed and/or disposed on and/or in the apparatus chip 210, bridge chip(s) 205, and/or delivery chip(s) 215. In various embodiments, the signal management system further comprises optical elements formed and/or disposed on and/or in one or more external chips 300 that are external to the cryogenic and/or vacuum chamber 40. For example, the one or more optical elements formed and/or disposed on and/or in the one or more external chips 300 are coupled to respective optical elements formed and/or disposed on and/or in the apparatus chip 210, bridge chip(s) 205, and/or delivery chip(s) 215 via optical fibers 86 and/or free space optics, in various embodiments.

In various embodiments, the quantum computing system 100 comprises a computing entity 10 and a quantum computer 110. In various embodiments, the quantum computer 110 comprises a controller 30 and a quantum processor 115. In various embodiments, the quantum processor comprises a cryogenic and/or vacuum chamber 40 enclosing an optics-integrated confinement apparatus system 200 (e.g., an ion trap), one or more external chips 300 comprising components of the signal management system, one or more voltage sources 50 configured to provide voltage signals to the electrical components of the optics-integrated confinement apparatus system 200.

In various embodiments, the cryogenic and/or vacuum chamber 40 is a temperature and/or pressure-controlled chamber. For example, the quantum computer system 100 may comprise vacuum and/or temperature control components that are operatively coupled to the cryogenic and/or vacuum chamber 40.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding electrode elements (e.g., electrodes) of the confinement apparatus 200, in an example embodiment. For example, the electric and/or electromagnetic field formed at least in part by applying the voltage signals generated by the voltage source 50 to the electrical elements of the confinement apparatus cause and/or form the confinement region(s) of the confinement apparatus.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control and/or in electrical communication with the voltage sources 50, cryogenic system and/or vacuum system controlling the temperature and/or pressure within the cryogenic and/or vacuum chamber 40, manipulation sources 60, photodetectors 70, and/or other systems controlling various environmental conditions (e.g., temperature, pressure, and/or the like) within the cryogenic and/or vacuum chamber 40 and/or configured to manipulate and/or cause a controlled evolution of quantum states of one or more quantum objects within the confinement apparatus. For example, the controller 30 may cause a controlled evolution of quantum states of one or more quantum objects within the confinement apparatus to execute a quantum circuit and/or algorithm. For example, the controller 30 may cause a reading procedure comprising coherent shelving to be performed, possibly as part of executing a quantum circuit and/or algorithm. In various embodiments, the quantum objects confined within the confinement apparatus are used as qubits of the quantum processor 115 and/or quantum computer 110.

### Example Optics-Integrated Confinement Apparatus

In various embodiments, the optics-integrated confinement apparatus system 200 comprises a confinement apparatus 212. The confinement apparatus 212 comprises a plurality of electrical elements such as electrodes, in an example embodiment, that are configured to generate a confining potential. In various embodiments, the plurality of electrodes of the confinement apparatus 212 are formed and/or disposed on a confinement apparatus chip 210. For example, the controller 30 may control the voltage sources 50 to provide electrical signals to the electrodes of the confinement apparatus 212 such that the electrodes generate a confining potential. The confining potential is configured to confine a plurality of quantum objects within a confinement volume defined by the confinement apparatus 212. For example, in an example embodiment, the confinement apparatus 212 is a surface ion trap and the confinement volume is a volume located proximate the surface of the surface ion trap. In various embodiments, the electrodes and/or confining potential are configured to define a plurality of defined positions within the confinement volume.

In various embodiments, the defined positions are disposed in a one-dimensional or two-dimensional lay out. For example, in an example embodiment, the defined positions are disposed along an axis of a linear configuration of electrical elements of the optics-integrated confinement apparatus. In another example embodiment, the defined positions are disposed in a two-dimensional array or layout defined by a two-dimensional configuration of electrical elements of the optics-integrated confinement apparatus. An example confinement apparatus comprising a linear configuration of electrical elements is described by U.S. application Ser. No. 16/717,602, filed Dec. 17, 2019, though various other confinement apparatuses having linear electrical element configurations may be used in various embodiments. Some example confinement apparatuses having two-dimensional electrical element configurations are described by U.S. application Ser. No. 17/533,587, filed Nov. 23, 2021, and U.S. application Ser. No. 17/810,082, filed Jun. 30, 2022, though various other confinement apparatuses having two-dimensional electrical element configurations may be used in various embodiments. The contents of U.S. application Ser. No. 16/717,602, filed Dec. 17, 2019, U.S. application Ser. No. 17/533,587, filed Nov. 23, 2021, U.S. application Ser. No. 17/810,082, filed Jun. 30, 2022, are incorporated herein by reference in their entireties.

In various embodiments, the voltage sources 50 provide respective electrical signals to the respective electrical elements (e.g., respective electrodes of the sequences of electrodes 220) of the confinement apparatus 212, such that a confining potential is formed. Based on the contours and time evolution of the confining potential (controlled by the controller 30 via controlling the operation of the voltage sources 50) one or more quantum objects are confined at respective defined positions 225 (e.g., 225A, 225C), moved between defined positions and/or the like. When a quantum object is located at a defined position, one or more functions (e.g., quantum computing functions) may be performed on the quantum object. An example function that may be performed on quantum object is photoionization of the quantum object. For example, a manipulation signal 61 (e.g., 61A, 61B) may be applied to the quantum object (e.g., an atom or molecule) to photo ionize the quantum object.

Another example function that may be performed on a quantum object is state preparation of the quantum object. For example, one or more manipulation signals 61 may be applied to the quantum object to prepare the quantum object in a particular quantum state. For example, the particular quantum state may be a state within a defined qubit space used by the quantum computer such that the quantum object may be used as a qubit of the quantum computer.

Another example function that may be performed on a quantum object is reading a quantum state of the quantum object. For example, a manipulation signal 61 (e.g., a reading signal) may be applied to the quantum object. When the quantum object's wave function collapses into a first state of the qubit space, the quantum object will fluoresce in response to the reading signal being applied thereto. When the quantum object's wave function collapses into a second state of the qubit space, the quantum object will not fluoresce in response to the reading signal being applied thereto. A photodetector 70 (e.g., 70A, 70C) configured to receive signals emitted by a quantum object disposed at a respective defined position 225 may then detect whether or not the quantum object fluoresced such that the quantum state of the quantum object is determined.

Another example function that may be performed on a quantum object is cooling the quantum object or a quantum object crystal comprising the quantum object. A quantum object crystal is a pair or set of quantum objects where at least one of the quantum objects of the quantum object crystal is qubit quantum object used as a qubit of the quantum computer and at least one quantum objects of the quantum object crystal is used to perform sympathetic cooling of the qubit quantum object. For example, a manipulation signal 61 (e.g., a cooling signal or a sympathetic cooling signal) may be applied to the quantum object or quantum object crystal to cause the (qubit) quantum object to be cooled (e.g., reduce the vibrational and/or other kinetic energy of the (qubit) quantum object).

Another example function that may be performed on a quantum object is shelving the quantum object. In various embodiments, quantum objects in the second state of the qubit space may be shelved during the performance of a reading function. For example, a shelving operation may comprise causing the quantum state of a quantum object in the second state of the qubit space to evolve to an at least meta-stable state outside of the qubit space while a reading operation is performed. An example shelving process is describe by U.S. Application No. 63/200,263, filed Feb. 25, 2021, though various other shelving processes may be used in various embodiments. In various embodiments, the shelving of a quantum object is performed by applying one or more manipulation signals to the quantum object to cause the quantum object's quantum state to evolve to an at least meta-stable state outside of the qubit space when the quantum object is in the second state of the qubit space.

Another example function that may be performed on a quantum object is (optical) repumping of the quantum object. In various embodiments, repumping of the quantum object comprises applying one or more manipulation signals 61 to the quantum object to cause the quantum state of the quantum object to evolve to an excited state.

Another example function that may be performed on a quantum object is performing a single qubit gate on the quantum object. For example, one or more manipulation signals 61 may be applied to the quantum object to perform a single qubit quantum gate (e.g., a single qubit logical function) on the quantum object.

Another example function that may be performed on a quantum object is performing a two-qubit gate on the quantum object. For example, one or more manipulation signals 61 may be applied to a pair or set of quantum objects that includes the quantum object to perform a two qubit (or three, four, or more) quantum gate (e.g., a multiple qubit logical function) on the quantum object and the at least one other quantum object.

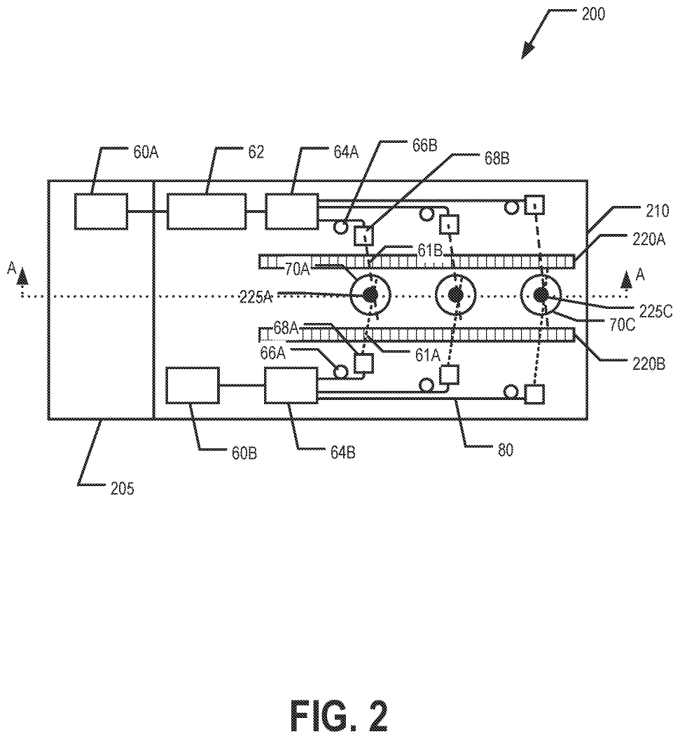

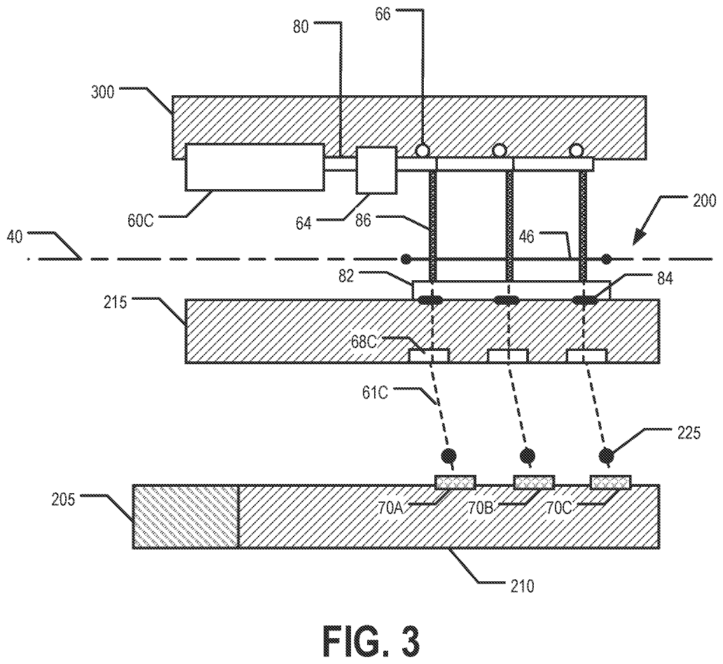

FIG. 2 provides a top view of at least a portion of an optics-integrated confinement apparatus system 200 and FIG. 3 provides a cross-sectional view of at least a portion of an optics-integrated confinement apparatus system 200 taken along the AA line shown in FIG. 2.

As illustrated in FIG. 2, the optics-integrated confinement apparatus system 200 comprises a confinement apparatus chip 210. In various embodiments, the confinement apparatus chip 210 is a substrate comprising electrical elements, such as sequences of electrodes 220 (e.g., 220A, 220B), that are configured to generate the confining potential of the optics-integrated confinement apparatus system 200. As noted above, in various embodiments, the sequences of electrodes may be configured to define one-dimensional or two-dimensional confinement regions that define a plurality of define positions 225 (e.g., 225A, 225C).

In various embodiments, the confinement apparatus chip 210 further comprises at least one optical element disposed and/or formed on and/or in the confinement apparatus chip 210. For example, as shown in FIG. 2, one or more manipulation sources 60 (e.g., 60B), amplifiers 62, beam splitters 64 (e.g., 64A, 64B), optical modulators 66 (e.g., 66A, 66B), signal manipulation elements 68 (e.g., 68A, 68B), photodetectors 70, waveguides 80, grating couplers, edge couplers, tapers, reference cavities, light absorbing structures, anti-reflective coatings, routing elements, resonant structures, and/or other optical elements are formed and/or disposed on and/or in the confinement apparatus chip 210.

As shown in FIGS. 2 and 3, the optics-integrated confinement apparatus system 200 further comprises one or more bridge chips 205, in various embodiments. In various embodiments, the confinement apparatus chip 210 defines an apparatus plane. Each bridge chip 205 defines a respective bridge plane that is coplanar with the apparatus plane. Each of the one or more bridge chips 205 has one or more optical elements disposed and/or formed thereon and/or therein. For example, FIG. 2 illustrates a manipulation source 60A formed on the bridge chip 205. In various embodiments, one or more optical elements, including one or more of one or more manipulation sources 60, amplifiers 62, beam splitters 64, optical modulators 66, signal manipulation elements 68, photodetectors 70, waveguides 80, grating couplers, edge couplers, tapers, reference cavities, light absorbing structures, anti-reflective coatings, routing elements, resonant structures, and/or other optical elements are formed and/or disposed on and/or in one or more bridge chips 205.

As shown in FIG. 3, in various embodiments the optics-integrated confinement apparatus system 200 further comprises one or more delivery chips 215. The illustrated example delivery chip 215 is a cloud chip. In various embodiments, each cloud chip is a delivery chip 215 that defines a cloud plane that is substantially parallel to the apparatus plane but not coplanar with the apparatus plane. The delivery chip 215 has one or more optical elements disposed and/or formed thereon and/or therein. For example, FIG. 3 illustrates couplers 84 (e.g., grating couplers, edge couplers, and/or the like) and signal manipulation elements 68 (e.g., 68C) formed on the delivery chip 215. In various embodiments, one or more optical elements, including one or more of one or more manipulation sources 60, amplifiers 62, beam splitters 64, optical modulators 66, signal manipulation elements 68, photodetectors 70, waveguides 80, grating couplers, edge couplers, tapers, reference cavities, light absorbing structures, anti-reflective coatings, routing elements, resonant structures, and/or other optical elements are formed and/or disposed on and/or in one or more delivery chips 215.

In an example embodiment, the signal management system comprises one or more manipulation sources 60 (e.g., 60C) formed and/or disposed on one or more external chips 300 that are disposed external to the cryogenic and/or vacuum chamber 40. Manipulation signals 61 (e.g., 61C) generated by the manipulation sources 60 formed and/or disposed on an external chip 300 may be provided to the defined positions 225 located within the cryogenic and/or vacuum chamber via free space optics and/or optical fibers 86 (or other waveguides 80) through a window or pass through 46 formed in the cryogenic and/or vacuum chamber 40. In various embodiments, the optical fibers 86 are coupled to the delivery chip 215, bridge chip 205, and/or confinement apparatus 215 via a fiber block 82. In various embodiments, the fiber block 82 secures the optical fibers 86 to the respective chip of the optics-integrated confinement apparatus system 200 and aligns the core of the respective optical fibers 86 with the respective optical paths of the optics-integrated confinement apparatus. For example, the fiber block 82 aligns the optical fibers 86 with respective couplers 84 of the bridge chip 215.

In various embodiments, the one or more manipulation sources 60 (formed and/or disposed on and/or in the confinement apparatus chip 210, bridge chip 205, delivery chip 215, and/or an external chip 300) comprise one or more lasers (e.g., optical lasers, microwave sources, and/or the like). In various embodiments, each manipulation source 60 is configured to generate a manipulation signal 61 having a respective characteristic wavelength in the microwave, infrared, visible, or ultraviolet portion of the electromagnetic spectrum. For example, the respective characteristic wavelength is configured to cause and/or control one or more particular quantum state evolutions of a quantum object. In various embodiments, the one or more manipulation signals 61 are configured to manipulate and/or cause a controlled quantum state evolution of one or more quantum objects confined by the optics-integrated confinement apparatus system 200. For example, in an example embodiment, wherein the one or more manipulation sources 60 comprise one or more lasers, the lasers may provide one or more laser beams to defined positions where respective quantum objects are positioned.

For example, a manipulation source 60 generates a manipulation signal 61 that is provided to one or more defined positions 225 via respective beam splitters 64, waveguides 80, signal manipulation elements 68, and/or the like. In an example embodiment, one or more optical modulators 64 are configured to control which defined positions of one or more defined positions 225 upon which the manipulation signal 61 is incident.

In various embodiments, the manipulation sources 60 comprise one or more on chip lasers, stimulated Brillouin scatting (SBS) lasers, external cavity lasers, and/or the like. For example, the manipulation sources 60 may include one or more lasers configured to be disposed within the cryogenic and/or vacuum chamber 40, as described by U.S. 63/363,506, filed Apr. 25, 2022, the content of which is incorporated by reference herein in its entirety. For example, in an example embodiment, a manipulation source 60 uses injection locking or injection seeding using an incident laser beam (e.g., generated by a laser external to the cryogenic and/or vacuum chamber 40) to ensure a narrow line width and/or accurate frequency of the resulting manipulation signal 61.

In various embodiments, the one or more amplifiers 62 (formed and/or disposed on and/or in the confinement apparatus chip 210, bridge chip 205, delivery chip 215, and/or an external chip 300) comprise one or more resonance cavities, reflective semiconductor optical amplifiers (RSOAs), on-chip amplifiers, harmonic generators, and/or other optical amplifiers. In various embodiments, the amplifiers 62 may be positioned upstream and/or downstream of respective beam splitters 64.

In various embodiments, the one or more beam splitters 64 (formed and/or disposed on and/or in the confinement apparatus chip 210, bridge chip 205, delivery chip 215, and/or external chip 300) comprise 1: N beam splitters where N is a positive integer determined on the application. In various embodiments, the beam splitters 64 are configured to handle optical beams of sufficient power for performing the respective functions of the quantum computer while exhibiting minimal power absorption. In an example embodiment, the one or more beam splitters 64 includes a multimode interferometer (MMI) splitter.

In various embodiments, the one or more optical modulators 66 (formed and/or disposed on and/or in the confinement apparatus chip 210, bridge chip 205, delivery chip 215, and/or an external chip 300) comprise one or more on-chip modulators; modulators with integrated detectors and configured to stabilize optical beam parameters such as intensity, phase, and/or frequency; and/or other optical modulators. In an example embodiment, one or more modulators 66 operate on utilization of thermal, stress-optic, acousto-optic, or electro-optic effects. In an example embodiment, one or more modulators 66 use the electro-optics effects of lithium niobate (LiNbO₃) or a similar material to provide a Si₃N₄-based modulator. In various embodiments, at least one of the one or more modulators 66 is a switching modulator that displays high (e.g., greater than 60 dB or greater than 90 dB) extinction when in the off state. Moreover, the modulators 66 are able to handle optical beams of sufficient power for performing the respective functions of the quantum computer while exhibiting minimal power absorption.

In various embodiments, the one or more signal manipulation elements 68 (formed and/or disposed on and/or in the confinement apparatus chip 210, bridge chip 205, delivery chip 215, and/or an external chip 300) comprise one or more of diffractive optics elements (DOEs), such as lenses, mirrors, and/or the like; passive metamaterial arrays; active metamaterial arrays; and/or the like. For example, the one or more signal manipulation elements may be similar to those describe by U.S. application Ser. No. 17/653,979, filed Mar. 8, 2022, and/or U.S. Application No. 63/363,506, filed Apr. 25, 2022, the contents of which are incorporated by reference herein in their entireties. For example, a signal manipulation element such as a metamaterial array (also known as a metasurface) is configured to control one or more of the wavelength, focus, polarization, phase, direction of propagation, and/or intensity of an induced beam resulting from a laser beam, for example, being incident thereon. In an example embodiment, a signal manipulation element is configured to focus a manipulation signal 61 onto a defined position 225 such that the optical power delivered to a quantum object located at the defined position 225 is sufficient to perform the corresponding function of the quantum computer while reducing the power density within one or more corresponding waveguides 80 configured to deliver the manipulation signal 61 to the respective signal manipulation element 68.

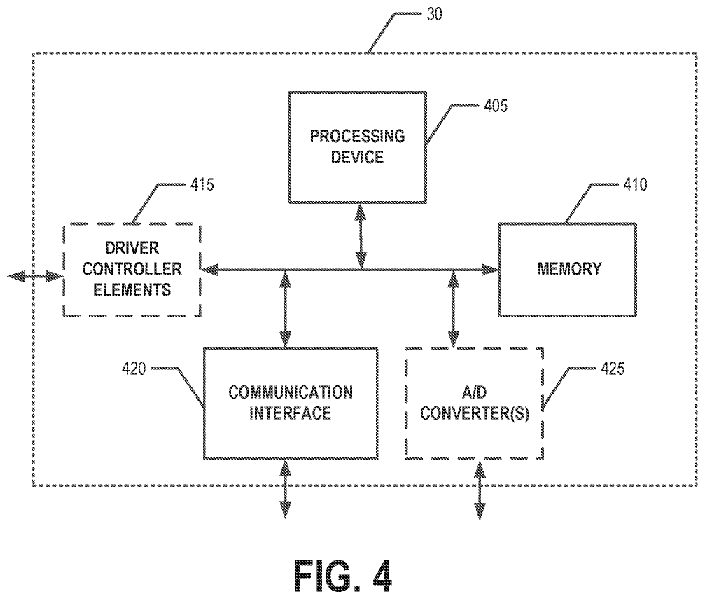

In various embodiments, one or more photodetectors 70 are formed and/or disposed on and/or in the confinement apparatus chip 210, bridge chip 205, delivery chip 215 of the optics-integrated confinement apparatus system 200. For example, a photodetector 70 is configured to detect one or more photons emitted by a quantum object located at a respective defined position of the optics-integrated confinement apparatus system 200. In various embodiments, the photodetectors 70 may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer and/or quantum objects. In various embodiments, the photodetectors 70 are in electronic communication with the controller 30 via one or more A/D converters 425 (see FIG. 4) and/or the like. For example, a quantum object being read and/or having its quantum state determined may emit an emitted signal, at least a portion of which is incident on a photodetector 70 of the signal management system (e.g., formed and/or disposed on and/or in a surface of the confinement apparatus chip 210). The emitted signal being incident on the photodetector 70 causes the photodetector 70 to generate an electric signal that is passed to the controller 30.

In various embodiments, one or more waveguides 80 (e.g., low loss waveguides) are formed and/or disposed on and/or in confinement apparatus chip 210, bridge chip 205, delivery chip 215, and/or an external chip 300. In various embodiments, the waveguides 80 are low loss waveguides in that they exhibit optical losses of approximately 5 dB/cm or less at the respective wavelengths of optical beams to be transmitted along the respective waveguide. For example, in various embodiments, the waveguides 80 are formed of specially formed SiN and/or Al₂O₃ films that are configured to have low optical losses at short wavelengths (e.g., blue, purple, and/or ultraviolet wavelengths). In an example embodiment, one or more of the waveguides 80 includes a 90° circular bend with a bending radius of no more than 20 μm. In an example embodiment, waveguide 80 includes an offset between the straight and bending portions of the waveguide 80 to achieve better mode overlap at the junctions between straight and bending portions. In various embodiments, waveguides 80 include Euler bends, inverse-designed 90° bends, and/or the like. In various embodiments, the waveguides 80 are configured to transmit optical beams (e.g., manipulations signals 61) between various optical elements of the signal management system.

In various embodiments, the one or more optical elements formed and/or disposed on and/or in the confinement apparatus chip 210, bridge chip(s) 205, delivery chip(s) 215 comprise one or more couplers 84. In various embodiments, the couplers 84 comprise one or more grating couplers, edge couplers, tapers, and/or the like. In an example embodiment, grating couplers, edge couplers, and/or tapers are used to couple manipulation signals into one or more waveguides 80. In an example embodiment, a grating coupler is used to outcouple a manipulation signal 61 toward a defined position 225. In various embodiments, the grating couplers may include one or more of uniform grating couplers, apodized focusing grating couplers, two-dimensional grating couplers, and/or the like.

In various embodiments, an apodized focusing grating coupler is designed to deliver a focused beam of light to a respective defined position 225 at a respective wavelength, angle, and polarization (e.g., transverse electric (TE) or transverse magnetic (TM)). For example, the grating coupler may focus the manipulation signal 61 onto the defined position such that the optical power delivered to a quantum object located at the defined position 225 is sufficient to perform the corresponding function of the quantum computer while reducing the power density within one or more corresponding waveguides 80 configured to deliver the manipulation signal 61 to the coupler 84. In an example embodiment, an apodized focused grating coupler is configured to enable both forward and backward emission. In an example embodiment, an apodized focused grating coupler comprises a bottom reflector. In an example embodiment, a coupler 84 is a is a bi-layer apodized focused grating coupler that is only capable of emitting manipulation signals 61 in a direction toward the respective defined position 225.

In various embodiments, the couplers 84 include two-dimensional grating couplers that are capable of delivering circularly polarized manipulation signals 61 to defined positions 225. In various embodiments, a two-dimensional grating coupler includes two TE gratings with a 90° phase offset and a bottom reflector. In an example embodiment, a two-dimensional grating coupler includes comprises one or more photonic metasurfaces. In an example embodiment, the one or more photonic metasurfaces are configured to convert linearly polarized light to circularly polarized light. In an example embodiment, the one or more photonic metasurfaces are configured to rotate the polarization direction of linearly polarized light. In various embodiments, the one or more photonic metasurfaces are configured to generate and/or cause arbitrary polarization conversion, generate a phase profile of light emitted from/output by the coupler, act as a focusing element, and/or perform angle correction for grating outcoupled light.

In an example embodiment, the couplers 84 include angle-tuned couplers that use encapsulants with a tuned or tunable refractive index to control the beam steering of a manipulation signal outcoupled by the respective coupler 84. For example, the refractive index of an encapsulant of a coupler 84 may be tuned to fine-tune and/or optimize the delivery of the respective manipulation signal 61 to the respective defined position 225, to compensate for fabrication or design error and/or the like.

In various embodiments, the couplers 84 include edge couplers for coupling manipulations signals 61 into waveguides 80 from one or more optical fibers 86.

In various embodiments, various other optical elements may be formed and/or disposed on and/or in the confinement apparatus chip 210, bridge chip(s) 205, and/or delivery chip(s) 215. For example, optical local oscillators, reference cavities, and/or the like may be formed and/or disposed on and/or in the confinement apparatus chip 210, bridge chip(s) 205, and/or delivery chip(s) 215.

In various embodiments, one or more optical elements disposed and/or formed on and/or in the confinement apparatus chip 210, bridge chip(s) 205, and/or delivery chip(s) 215 are configured for use in performing on or more functions on one or more quantum objects disposed at respective defined positions.

In various embodiments, each of the optical elements of the optics-integrated confinement apparatus system 200 (e.g., disposed on and/or in the confinement apparatus chip 210, bridge chip(s) 205, and/or delivery chip(s) 215) are configured to operate under cryogenic (e.g., temperature less than 120 K) and/or ultra high vacuum (e.g., pressure less than 100 nanopascals) conditions.

In various embodiments, the confinement apparatus chip 210, bridge chip(s) 205, cloud chip(s) 210, and/or external chip(s) 300 are fabricated, at least in part, using pick-and-place technologies.

### Technical Advantages

Various embodiments provide technical solutions to the accurate and efficient delivery of manipulation signals to quantum objects and/or collecting indications of emitted signals emitted by quantum objects. These various solutions are scalable to provide signal delivery and/or collection for large one or multi-dimensional (e.g., two-dimensional) confinement apparatuses.

Conventionally, laser beams are provided to positions within an ion trap through the use of external lasers and free space optics configured to provide the laser beams to specific positions within the ion trap. However, the amount of space required for such beam paths, even to provide laser beams to a relatively small number of defined positions of the ion trap, is significant (e.g., a few square meters). Additionally, the accuracy with which the laser beams may be provided to the positions within the ion trap through such conventional means can limit the density of the defined positions of ion trap. Moreover, ion traps are generally utilized within a cryogenic and/or vacuum chamber. As such, the laser beams must be passed through the cryogenic and/or vacuum chamber and any radiation and/or thermal shields therein. Thus, a technical problem exists as to how to provide manipulation signals to a quantum object confinement apparatus that is able to scale with the size and/or dimensions of the quantum object confinement apparatus efficiently and accurately. These technical problems are compounded as the quantum object confinement apparatus is increased in size (e.g., as the number of positions defined for the quantum object confinement apparatus increases).

Various embodiments provide technical solutions to these technical problems. In particular, in various embodiments, optical elements of the signal management system are incorporated and/or integrated into an optics-integrated confinement apparatus. For example, one or more optical elements of the signal management system are disposed within the cryogenic and/or vacuum chamber. For example, one or more optical components of the signal management system are disposed on the confinement apparatus chip (which comprises the electrical elements that define the confinement apparatus and the positions thereof), one or more bridge chips, and/or one or more cloud chips of the optics-integrated confinement apparatus. These one or more optical elements include passive and/or active optical elements. For example, in an example embodiment, a manipulation signal is generated by an on-chip laser and/or the like formed on the confinement apparatus chip, bridge chip, and/or cloud chip. In various embodiments, the one or more elements formed and/or disposed on and/or in the confinement apparatus chip, bridge chip(s), and/or cloud chip(s) reduce the spatial requirements for free space optics beam path configurations, number of cryogenic and/or vacuum chamber pass throughs, and/or the like. Furthermore, the configuration of the optics-integrated confinement apparatus system of various embodiments reduces the additional technical problems of signal management systems of larger confinement apparatuses. Thus, various embodiments provide technical solutions to technical problems regarding how to provide manipulation signals to defined positions of a confinement apparatus such that manipulation signals efficiently and effectively provided to the defined positions, even when the defined positions form a two or three-dimensional array.

### Exemplary Controller

In various embodiments, an optics-integrated confinement apparatus system 200 is incorporated into a system (e.g., a quantum computer 110) comprising a controller 30. In various embodiments, the controller 30 is configured to control various elements of the system (e.g., quantum computer 110). For example, the controller 30 may be configured to control the voltage sources 50, a cryogenic system and/or vacuum system controlling the temperature and pressure within the cryogenic and/or vacuum chamber 40, manipulation sources 60, cooling system, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more quantum objects confined by the optics-integrated confinement apparatus system 200. In various embodiments, the controller 30 may be configured to receive signals from one or more photodetectors 70.

As shown in FIG. 4, in various embodiments, the controller 30 may comprise various controller elements including processing elements 405, memory 410, driver controller elements 415, a communication interface 420, analog-digital converter elements 425, and/or the like. For example, the processing elements 405 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 405 of the controller 30 comprises a clock and/or is in communication with a clock.

For example, the memory 410 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 410 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 410 (e.g., by a processing element 405) causes the controller 30 to perform one or more steps, operations, processes, procedures and/or the like described herein for providing manipulation signals to atomic object positions and/or collecting, detecting, capturing, and/or measuring indications of emitted signals emitted by quantum objects located at corresponding defined positions of the optics-integrated confinement apparatus system 200.

In various embodiments, the driver controller elements 410 may include one or more drivers and/or controller elements each configured to control one or more drivers. In various embodiments, the driver controller elements 410 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 405). In various embodiments, the driver controller elements 415 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the optics-integrated confinement apparatus system 200 (and/or other drivers for providing driver action sequences to potential generating elements of the optics-integrated confinement apparatus); cryogenic and/or vacuum system component drivers; cooling system drivers, and/or the like. In various embodiments, the controller 30 comprises means for communicating and/or receiving signals from one or more optical receiver components (e.g., photodetectors 70). For example, the controller 30 may comprise one or more analog-digital converter elements 425 configured to receive signals from one or more optical receiver components (e.g., a photodetector of the optics collection system), calibration sensors, and/or the like.

In various embodiments, the controller 30 may comprise a communication interface 420 for interfacing and/or communicating with a computing entity 10. For example, the controller 30 may comprise a communication interface 420 for receiving executable instructions, command sets, and/or the like from the computing entity 10 and providing output received from the quantum computer 110 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

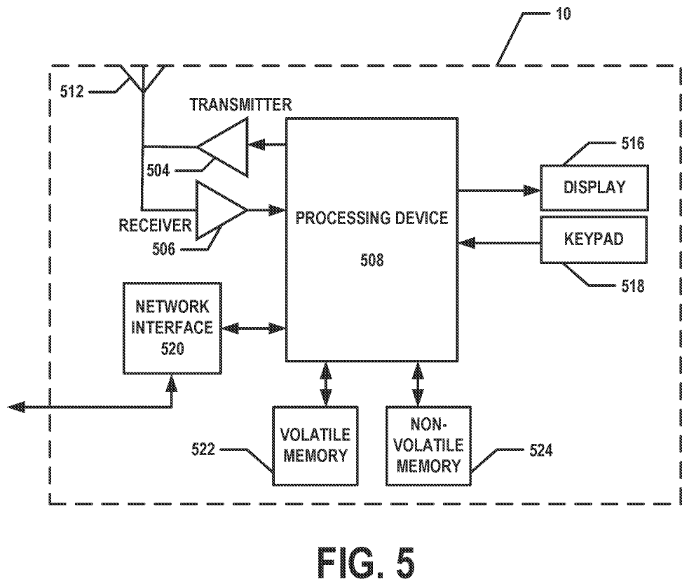

FIG. 5 provides an illustrative schematic representative of an example computing entity 10 that can be used in conjunction with embodiments of the present invention. In various embodiments, a computing entity 10 is configured to allow a user to provide input to the quantum computer 110 (e.g., via a user interface of the computing entity 10) and receive, display, analyze, and/or the like output from the quantum computer 110.

As shown in FIG. 5, a computing entity 10 can include an antenna 512, a transmitter 504 (e.g., radio), a receiver 506 (e.g., radio), and a processing element 508 that provides signals to and receives signals from the transmitter 504 and receiver 506, respectively. The signals provided to and received from the transmitter 504 and the receiver 506, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1×(1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 may comprise a network interface 520 for interfacing and/or communicating with the controller 30, for example. For example, the computing entity 10 may comprise a network interface 520 for providing executable instructions, command sets, and/or the like for receipt by the controller 30 and/or receiving output and/or the result of a processing the output provided by the quantum computer 110. In various embodiments, the computing entity 10 and the controller 30 may communicate via a direct wired and/or wireless connection and/or via one or more wired and/or wireless networks 20.

The computing entity 10 may also comprise a user interface device comprising one or more user input/output interfaces (e.g., a display 516 and/or speaker/speaker driver coupled to a processing element 508 and a touch screen, keyboard, mouse, and/or microphone coupled to a processing element 508). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 518 (hard or soft), a touch display, voice/speech or motion interfaces, scanners, readers, or other input device. In embodiments including a keypad 518, the keypad 518 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 522 and/or non-volatile storage or memory 524, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### CONCLUSION

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. An optics-integrated confinement apparatus system comprising:
a confinement apparatus chip having a confinement apparatus formed thereon and having at least one apparatus optical element disposed and/or formed thereon.

2. The optics-integrated confinement apparatus system of claim 1, wherein the at least one apparatus optical element comprises at least one of a diffractive optical element, a passive metasurface, an active metasurface, an optical modulator, a low loss waveguide, an amplifier, a laser, a photodetector, a grating coupler, a beam splitter, an edge coupler, an optical local oscillator, a taper, a reference cavity, a light absorbing structure, an anti-reflection coating, an optical routing element, or a resonant structures.

3. The optics-integrated confinement apparatus system of claim 1, further comprising at least one of (a) a bridge chip having at least one bridge optical element disposed and/or formed thereon or (b) a delivery chip having at least one delivery optical element disposed and/or formed thereon.

4. The optics-integrated confinement apparatus system of claim 3, wherein the at least one bridge optical element and/or the at least one delivery optical element comprises at least one of a diffractive optical element, a passive metasurface, an active metasurface, an optical modulator, a low loss waveguide, an amplifier, an on-chip laser, a photodetector, a grating coupler, an optical splitter, an edge coupler, an optical local oscillator, a taper, a reference cavity, a light absorbing structure, an anti-reflection coating, an optical routing element, or a resonant structures.

5. The optics-integrated confinement apparatus system of claim 3, wherein the delivery chip is a cloud chip.

6. The optics-integrated confinement apparatus system of claim 1, wherein the optics-integrated confinement apparatus system is configured for operation under cryogenic and/or ultra-high vacuum conditions.

7. The optics-integrated confinement apparatus system of claim 6, wherein at least one of (a) the at least one apparatus optical element, (b) the at least one bridge optical element, or (c) the at least one delivery optical element is configured to be coupled to an optical fiber configured to provide a manipulation signal generated outside of a cryogenic and/or vacuum chamber within which the optics-integrated confinement apparatus system is disposed to the at least one of (a) the at least one apparatus optical element, (b) the at least one bridge optical element, or (c) the at least one delivery optical element.

8. The optics-integrated confinement apparatus system of claim 7, wherein the at least one of (a) the at least one apparatus optical element, (b) the at least one bridge optical element, or (c) the at least one delivery optical element is configured to be coupled to the optical fiber via a fiber block.

9. The optics-integrated confinement apparatus system of claim 1, wherein the optics-integrated confinement apparatus system is fabricated at least in part using a pick-and-place technique.

10. A QCCD-based quantum system comprising:
a confinement apparatus (a) defining a plurality of positions, (b) operable to confine quantum objects, and (c) formed on a confinement apparatus chip, wherein the confinement apparatus is operable to confine respective quantum objects at respective positions of the plurality of positions and cause transportation of respective quantum objects between the respective positions of the plurality of positions;
a signal manipulation system configured to cause delivery of optical signals to at least one of the respective positions, the signal manipulation system comprising at least one apparatus optical element disposed and/or formed on the confinement apparatus chip.

11. The system of claim 10, wherein the at least one apparatus optical element comprises at least one of a diffractive optical element, a passive metasurface, an active metasurface, an optical modulator, a low loss waveguide, an amplifier, a laser, a photodetector, a grating coupler, a beam splitter, an edge coupler, an optical local oscillator, a taper, a reference cavity, a light absorbing structure, an anti-reflection coating, an optical routing element, or a resonant structures.

12. The system of claim 10, wherein the signal management system further comprises at least one of (a) a bridge chip having at least one bridge optical element disposed and/or formed thereon or (b) a delivery chip having at least one delivery optical element disposed and/or formed thereon.

13. The system of claim 12, wherein the at least one bridge optical element and/or the at least one delivery optical element comprises at least one of a diffractive optical element, a passive metasurface, an active metasurface, an optical modulator, a low loss waveguide, an amplifier, an on-chip laser, a photodetector, a grating coupler, an optical splitter, an edge coupler, an optical local oscillator, a taper, a reference cavity, a light absorbing structure, an anti-reflection coating, an optical routing element, or a resonant structures.

14. The system of claim 12, wherein the delivery chip is a cloud chip.

15. The system of claim 10, wherein the confinement apparatus and at least a portion of the signal management system is configured for operation under cryogenic and/or ultra-high vacuum conditions.

16. The system of claim 15, wherein at least one of (a) the at least one apparatus optical element, (b) the at least one bridge optical element, or (c) the at least one delivery optical element is configured to be coupled to an optical fiber configured to provide a manipulation signal generated outside of a cryogenic and/or vacuum chamber within which the optics-integrated confinement apparatus system is disposed to the at least one of (a) the at least one apparatus optical element, (b) the at least one bridge optical element, or (c) the at least one delivery optical element.

17. The system of claim 16, wherein the at least one of (a) the at least one apparatus optical element, (b) the at least one bridge optical element, or (c) the at least one delivery optical element is configured to be coupled to the optical fiber via a fiber block.

18. The system of claim 10, wherein at least one of (a) the at least one apparatus optical element, (b) the at least one bridge optical element, or (c) the at least one delivery optical element is part of a photonic integrated circuit disposed and/or formed on a respective one of (i) the apparatus chip, (ii) bridge chip, or (iii) delivery chip and the at least one photonic integrated circuit disposed and/or formed on the respective one of (i) the apparatus chip, (ii) bridge chip, or (iii) delivery chip is fabricated at least in part using a pick-and-place technique.

19. The system of claim 10, wherein the plurality of positions defines an array of positions and the signal management system is configured to selectively provide optical signals to set positions within the array of positions.

20. The system of claim 19, wherein the signal management system is configured to selectively provide the optical signals to the set positions within the array of positions substantially simultaneously.
